(19) United States
(12) Patent Application Publication
(10) Pub. No.: US 2007/0164431 A1
(43) Pub. Date: Jul. 19, 2007

(54) WAFER LEVEL CHIP SCALE PACKAGE HAVING REROUTING LAYER AND METHOD OF MANUFACTURING THE SAME

(75) Inventors: In Young LEE, Gyeonggi-do (KR); Hyun-Soo CHUNG, Gyeonggi-do (KR); Dong-Ho LEE, Gyeonggi-do (KR); Sung-Min SIM, Gyeonggi-do (KR); Dong-Soo SEO, Gyeonggi-do (KR); Seung-Kwan RYU, Gyeonggi-do (KR); Myeong-Soon PARK, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/549,933

(22) Filed: Oct. 16, 2006

(30) Foreign Application Priority Data
Jan. 14, 2006 (KR) 2006-4176

(51) Int. Cl. H01L 23/48; H01L 21/44

(52) U.S. Cl. 257/737; 438/613; 257/E23.02

(57) ABSTRACT

A wafer level chip scale package capable of reducing parasitic capacitances between a rerouting and the metal wiring of a wafer, and a method for manufacturing the same are provided. An embodiment of the wafer level chip scale package includes a wafer arranged with a plurality of bonding pads and an insulating member formed on the wafer so that the bonding pads are exposed. A rerouting is further formed on the insulating member in contact with the exposed bonding pads and an external connecting terminal is electrically connected to a portion of the rerouting. Here, the insulating member overlapping the rerouting is provided with a plurality of spaces in which air is trapped.

### CROSS-REFERENCE TO RELATED PATENT APPLICATION

This application claims the benefit of Korean Patent Application Ser. No. 10-2006-4176, filed on Jan. 14, 2006 in the Korean Intellectual Property Office, the disclosure of which is incorporated by reference.

### BACKGROUND

1. Field of the Invention

The present invention relates to a wafer level chip scale package (WLCSP) and a method for manufacturing the same; and more particularly, to a wafer level chip scale package (WLCSP) manufactured on a wafer using a redistribution technique and a method for manufacturing the same.

2. Description of the Related Art

In the electronics industry, technical advances continue to allow devices to be reduced in size while having equal or greater technical abilities. In the semiconductor package field, these advances generally center around a reduction in the size of the package on a chip level. One area of recent interest in this field has been the arrangement and implementation of chip scale packages on a wafer using redistribution or rerouting technology.

The redistribution (or rerouting) technology focuses on re-distributes positions for solder balls, in which the solder balls are bonded by a rerouting (or metal wiring). As conventional solder balls are generally bonded on set aluminum pads on a wafer, they may become too close to neighboring solder balls as the density of the solder balls increases resulting in possible shorts between neighboring solder balls. Thus, with the redistribution (or rerouting) technology, metal wiring may be formed on regions where aluminum pads are sparsely arranged, where the metal wiring connects the aluminum pads in the densely packed region to solder balls, which are bonded on the metal wiring. Here, the metal wiring is called rerouting, and the resulting varied arrangement of the solder balls is referred to as redistribution.

However, when the rerouting metal wiring overlaps with the metal wiring of a semiconductor device, a parasitic capacitance may be generated. The parasitic capacitance in turn may cause transmission delays of external signals input through the solder balls.

Therefore, an approach capable of reducing the influence of the parasitic capacitances generated when redistribution (or rerouting) technology is used is needed.

### SUMMARY

The present invention provides a wafer level chip scale package capable of reducing parasitic capacitance between a rerouting and the metal wiring of semiconductor device in the wafer level chip scale package, and a method for manufacturing such a package.

According to an embodiment of the present invention a wafer level chip scale package includes a wafer arranged with a plurality of bonding pads and an insulating member formed on the wafer so that the bonding pads are exposed. A rerouting may then be formed on the insulating member in contact with the exposed bonding pads and an external connecting terminal can be electrically connected to a part of the rerouting. Here, the insulating member overlapping the rerouting includes a plurality of spaces in which air is trapped.

### BRIEF DESCRIPTION OF THE DRAWINGS

The above and other features and advantages of the present invention will become more apparent by describing in detail exemplary embodiments thereof with reference to the attached drawings, in which:

FIGS. 1 through 6 are process-specific cross-sectional views explaining a method for manufacturing a wafer level chip scale package according to embodiments of the present invention;

FIG. 7 is a top plan view illustrating a first interlayer insulating layer having a mesh region in accordance with an embodiment of the present invention;

FIG. 8 is a top plan view illustrating a first interlayer insulating layer in accordance with another embodiment of the present invention;

FIG. 9 is a cross-section view of a wafer level chip scale package according to another embodiment of the present invention; and

FIGS. 10 through 13 are process-specific cross-sectional views explaining a method of manufacturing a wafer level chip scale package in accordance with another embodiment of the present invention.

### DETAILED DESCRIPTION

The present invention will now be described more fully hereinafter with reference to the accompanying drawings, in which exemplary embodiments of the invention are shown. This invention may, however, be embodied in many different forms and should not be construed as being limited to the embodiments set forth herein. Rather, these embodiments are provided so that this disclosure will be thorough and complete, and will fully convey the scope of the invention to those skilled in the art. Further, the drawings may not be scale and the thicknesses of layers and regions illustrated in the drawings may be exaggerated for clarity. Like numbers refer to like elements throughout the specification.

The present invention is adapted to trap air in an interlayer insulating layer overlapping a rerouting. That is, because the air, which has a dielectric constant lower than that of the interlayer insulating layer, which may for example be a polyimide-based layer, is trapped between the rerouting and a metal wiring it is possible to reduce parasite capacitance. Thus, in the following embodiments, various interlayer insulating layers in which the air is trapped will be shown.

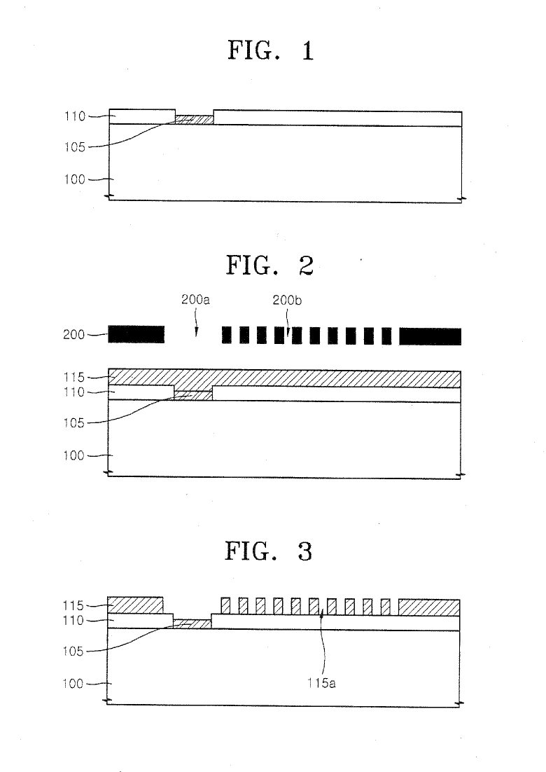

FIGS. 1 through 6 are process-specific cross-sectional views explaining a method for manufacturing a wafer level chip scale package according to embodiments of the present invention,

First, referring to FIG. 1, a wafer 100 formed with a pad 105 is provided. While not shown, the wafer 100 may be formed with semiconductor circuit elements and wirings, and the pad 105 may be formed on the resulting wafer 100 and electrically connected with the semiconductor circuit elements and wirings, The pad 105 may be formed of, for example, an aluminum metal layer. A passivation layer 110 is formed on the wafer 100 having the pad 105, and then partly etched so that a surface of the pad 105 is exposed. Here, the passivation layer 110 may employ a silicon nitride layer by way of example.

Referring to FIG. 2, a first interlayer insulating layer 115 is formed on the passivation layer 110. The first interlayer insulating layer 115 may be called a polymer layer and serves to absorb or release thermal stress. The first interlayer insulating layer 115 may be mainly formed of polyimides, polybenzoxazoles (PBOs), benzocyclobutenes (BCBs), or epoxies, and may be formed by an ordinary spin coating method, for example.

Next, a photo mask 200 is aligned over the wafer 100 having the first interlayer insulating layer 115. The photo mask 200 is provided to open the pad 105 and form a mesh region at a predetermined portion of the first interlayer insulating layer 115. The photo mask 200 includes open regions 200a and 200b for exposing the pad 105 and the predetermined portion of the first interlayer insulating layer 115.

Referring to FIG. 3, the first interlayer insulating layer 115 is exposed in a pattern determined by the openings 200a and 200b of the photo mask 200, and then the exposed first interlayer insulating layer 115 is removed by a developing solution. Thus, the pad 105 is again exposed, and a predetermined region of the interlayer insulating layer 115 is formed with a plurality of spaces 115a. The portion-at which the plurality of spaces 115a are formed is to overlap at least a portion of where the rerouting will be formed in the future. Here, each of the spaces 115a may have a diameter of about 0.1 ˜100 μm, so that it may be called a mesh. Hereinafter, a region in which the plurality of spaces, meshes 115a, are distributed is referred to as a mesh region 116 (refer to FIG. 7). The first interlayer insulating layer 115 may then be subject to a hardening process, in which it may be held at a temperature between about 200 and about 350 ° C. for 2 hours or so.

Here, FIG. 7 is a top plan view illustrating a first interlayer insulating layer 115 having a mesh region 116. The mesh region 116 is classified into a first region 116a to be formed with a rerouting and a second region 116b to be bonded with a solder ball. The second region 116b to be bonded with the solder ball may have a larger size than that of the first region 116a to be formed with the rerouting.

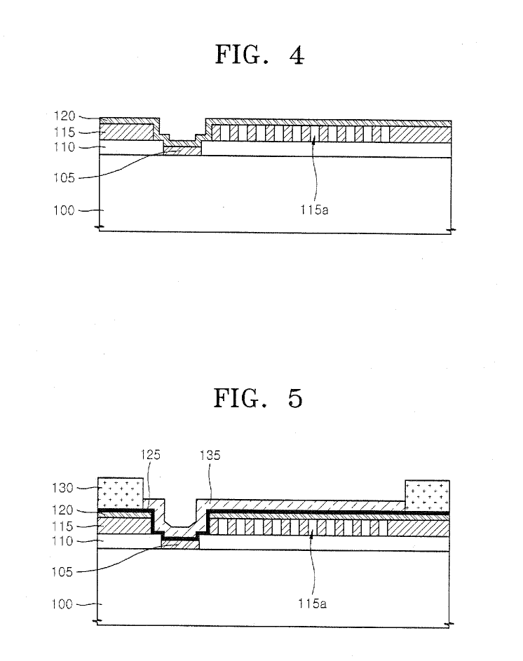

Next, as illustrated in FIG. 4 a second interlayer insulating layer 120 is formed on the first interlayer insulating layer 115 having the mesh region 116. The second interlayer insulating layer 120 should be formed so as to be able to trap air in the meshes 115a without filling the meshes 115a. The second interlayer insulating layer 120 may make use of a high viscosity material such as epoxy, or be laminated like a thin film.

Referring to FIG. 5, the second interlayer insulating layer 120 is etched so that the pad 105 is exposed, and then a first metal layer 125 is formed on the exposed pad 105 and the second interlayer insulating layer 120. The first metal layer 125 may be, for instance, a seed metal layer and be formed to include a Ti/Cu, TiW/NiV, Ti/TiV or Ti/Ni/Cu layer. The first metal layer 125 may be formed by sputtering or chemical vapor deposition, for example to a thickness of about 300 to about 3000 Å. Next, in order to define a rerouting on the first metal layer 125, a resist pattern 130 is formed so that the pad 105 and mesh region 116 are exposed. The resist pattern 130 may be formed by a known photolithography process. Subsequently, a second metal layer 135, which may be a main metal layer, is formed on the exposed first metal layer 125 using the resist pattern 130. The second metal layer 135 is selectively formed to include a copper containing metal layer, for example a Cu/Ti layer, on the first metal layer 125 using the resist pattern 130. The second metal layer 135 may be formed by sputtering or plating. When the second metal layer 135 is formed by plating, the first metal layer 125 becomes a plating electrode. The second metal layer 135 may be formed to a thickness of about 2,000 to about 15,000 Å.

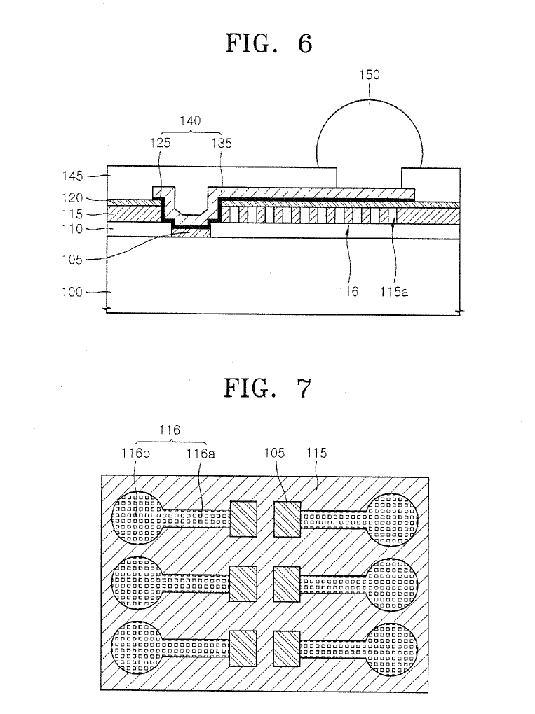

As shown in FIG. 6, the resist pattern 130 is removed by a known method, and then the first metal layer 125 is etched using the second metal layer 135 as a mask. The etched first metal layer 125 and the second metal layer 135 thereby form a rerouting 140. At this time, the mesh region 116 of the first interlayer insulating layer 115 is located under the rerouting 140.

A third interlayer insulating layer 145 is formed on the resulting wafer 100 having the rerouting 140. The third interlayer insulating layer 145 may be mainly formed to include polyimides, PBOs, BCBs, or epoxies, like the first interlayer insulating layer 115. Next, a portion of the third interlayer insulating layer 145 may be removed so that a portion of the rerouting 140 corresponding to the area where a solder ball will be bonded is exposed. A solder ball 150 is then bonded to the substrate including the rerouting 140 so as to contact the exposed rerouting 140.

In this embodiment of the present invention, the mesh region 116 is formed in the insulating layers, i.e. the first interlayer insulating layer 115, overlapping in location with the rerouting 140. Thus, air may be trapped in each mesh space 115a underlying a portion of the rerouting 140. As discussed above, because the air has the dielectric constant lower than that of the polyimide-based interlayer insulating layer 115, the parasite capacitance generated between the rerouting 140 and the metal wiring in the wafer 100 may be reduced by the air trapped in the mesh spaces 115a.

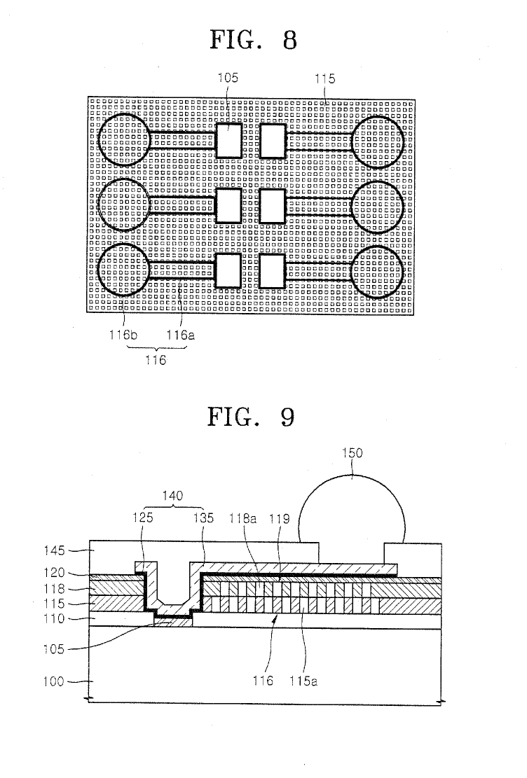

Further, although in this embodiment the mesh spaces 115a are formed only in the first interlayer insulating layer 115 underlying the rerouting 140, they may be formed in a smaller or larger portion of the first interlayer insulating layer 115 or may even be formed throughout the first interlayer insulating layer 115 as shown in FIG. 8. The mesh spaces 115a formed throughout the first interlayer insulating layer 115 may be formed through a photo mask (not shown) at the same time when the pad 105 is opened, as in the aforementioned embodiment. Additionally, although the mesh spaces 115a are formed in the first interlayer insulating layer 115 in this embodiment, the mesh spaces may be formed in other insulating layers above the first insulating layer.

FIG. 9 is a cross-section view of a wafer level chip scale package according to another embodiment of the present invention.

Referring to FIG. 9, a fourth interlayer insulating layer 118 having a second mesh region 119 may be additionally interposed between the first interlayer insulating layer 115 having the mesh region 116 and the second interlayer insulating layer 120. The second mesh region 119 of the fourth interlayer insulating layer 118 may overlap with the mesh region 116 of the first interlayer insulating layer 115. Each mesh space 118a of the fourth interlayer insulating layer 118 may alternate with each mesh space 115a of the first interlayer insulating layer 115, or the mesh spaces 118a may partially overlap the mesh spaces 115a. This alternating mesh structure may further enhance the insulating effects because more air may be trapped between the rerouting 140 and the metal wiring formed on the wafer 100.

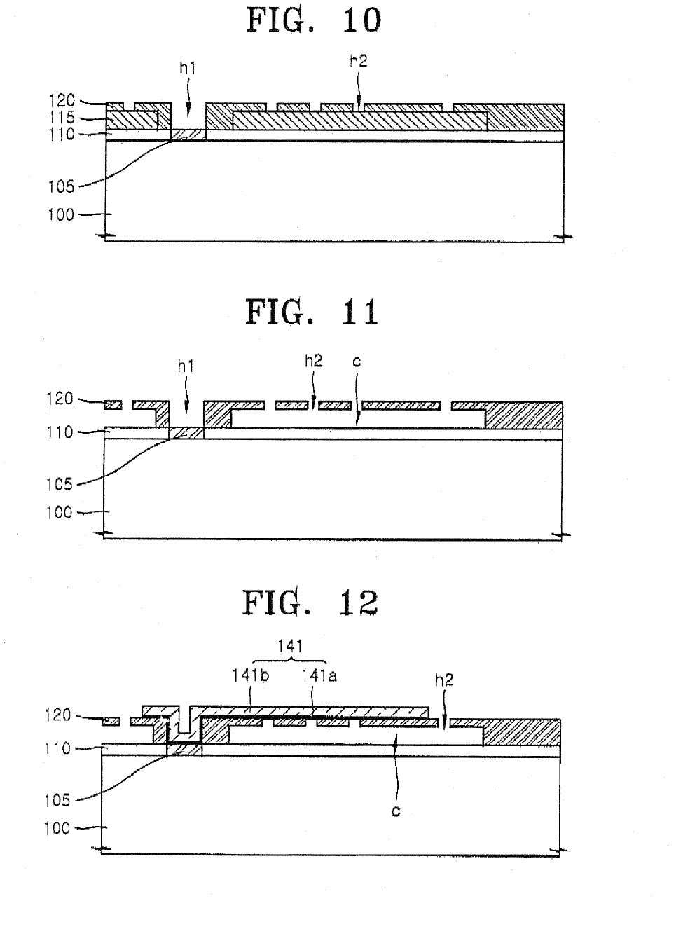

FIGS. 10 through 13 are process-specific cross-sectional views explaining a method of manufacturing a wafer level chip scale package in accordance with another embodiment of the present invention.

Referring to FIG. 10, a passivation layer 110 is formed on a wafer 100 having a pad 105, and then partly etched so that the pad 105 is exposed. A first interlayer insulating layer 115 may then be formed on a predetermined portion of the passivation layer 110. The first interlayer insulating layer 115 may then be partially patterned on a region overlapping an area where a rerouting will be formed. That is, a portion of the first interlayer insulating layer 115 may be removed for example, by a developing solution after being exposed under a photoresist mask. The first interlayer insulating layer 115 may be formed to include a material that is easily patterned.

A second interlayer insulating layer 120 is formed on the wafer 100 having the first interlayer insulating layer 115. The second interlayer insulating layer 120 may be formed to include a material having removal selectivity (or developing selectivity) such as polyimide, polybenzoxazole (PBO), benzocyclobutene (BCB), or epoxy. The second interlayer insulating layer 120 may be formed at a thickness thinner than that of the first interlayer insulating layer 115. Subsequently, the second interlayer insulating layer 120 may be partly exposed to light so that the pad 105 and a predetermined portion of the first interlayer insulating layer 115 can be exposed. The exposure process can be performed using a photo mask 200 (see FIG. 2) as in the aforementioned embodiment. Thereafter, the second interlayer insulating layer 120 exposed to light is removed by a developing solution, thereby forming a first hole h1 exposing the pad 105 in the second interlayer insulating layer 120, and second holes h2 exposing numerous portions of the first interlayer insulating layer 115. At this time, the second holes h2 may extend up to an interior the first interlayer insulating layer 115 by means of exposure intensity applied to the second interlayer insulating layer 120. To be specific, when an exposure amount applied to the second interlayer insulating layer 120 is sufficient, exposure energy is transmitted to the first interlayer insulating layer 115 under the second interlayer insulating layer 120. Thus, during the developing process, the first interlayer insulating layer 115 exposed to light can also be removed.

Here, each second hole h2 may be of sufficiently small size as compared to the first hole h1. For example, each second hole h2 may have about ½ to about 1/100 times as large a diameter as the first hole h1 exposing the pad 105.

Referring to FIG. 11, thereafter, the resulting wafer 100 is dipped into a developing solution for removing the first interlayer insulating layer 115 with the holes h1 and h2 formed in the second interlayer insulating layer 120. The first interlayer insulating layer 115 is removed by the developing solution introduced through the holes h2 in the second interlayer insulating layer 120. This process results in forming a cave c in the region where the first interlayer insulating layer 115 is removed.

As shown in FIG. 12, a metal layer 141 is formed on the second interlayer insulating layer 120 so as to come into contact with the exposed bonding pad 105. As stated above, the metal layer 141 may include a first metal layer 141a as a seed layer, and a second metal layer 14lb as a main layer. The first metal layer 141a may be formed by sputtering, while the second metal layer 141b may be formed by plating. At this time, as each second hole h2 has a sufficiently small size as compared to the first hole h1, and the first metal layer 141a is formed by the sputtering, which is low in step covering capability, the metal layer 141 may formed to bridge each of the holes h2 instead of flowing into them. Thus, the first metal layer 141a may be formed on the second interlayer insulating layer 120 without filling the second holes h2 or cave c. Thereafter, the second metal layer 141b is formed using the first metal layer 141a as a plating electrode, such that the second metal layer 141b is formed on the first metal layer 141a. The second and first metal layers 141b and 141a may then be patterned to form a rerouting 141. At this time, at least one of the second holes h2 may be exposed by the rerouting 141.

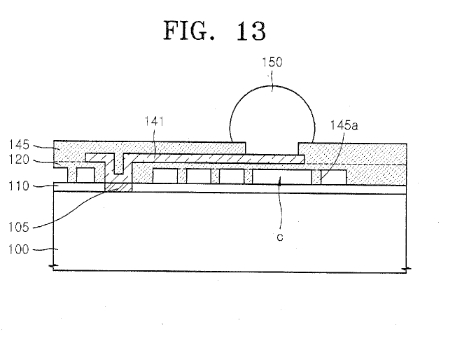

Referring to FIG. 13, a third interlayer insulating layer 145 is formed on the wafer 10 having the rerouting 141. When the third interlayer insulating layer 145 is deposited, the material of the third interlayer insulating layer 145 flows into the second holes h2 through an interface between the second interlayer insulating layer 120 and the rerouting 141, forming posts 145a in the cave c. The posts 145a may serve to support the second interlayer insulating layer 120. Thereafter, a portion of the third interlayer insulating layer 145 is removed so that a predetermined portion of the rerouting 141 is exposed. A external connecting terminal, such as a solder ball 150, may then be bonded so as to be connected to the exposed rerouting 141.

In this embodiment, the cave trapping the air is provided in the interlayer insulating layers 115 and 120, which is overlapped with the rerouting 141. This, in turn, may again greatly reduce the parasite capacitance between the rerouting 141 and metal wiring (not shown).

The present invention is not limited to the above embodiments. For, example, in these embodiments, the external connecting terminal makes use of, but is not limited to, the solder ball 150. Thus, a metal bump of copper (Cu), gold (Au), or nickel (Ni) can be used as the external connecting terminal instead of the solder ball 150.

As set forth above in detail, according to the present invention, spaces in which air is trapped are formed in the interlayer insulating layer overlapping the rerouting. Because the air spaces having a low dielectric constant are located between the rerouting and the metal wiring in the wafer, it may be possible to reduce the parasitic capacitance between the rerouting and the metal wiring. Consequently, a semiconductor package capable of high-speed operation can be manufactured.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A wafer level chip scale package, comprising:
a wafer including a bonding pad;
an insulating member formed on the wafer so that the bonding pad is exposed;
a rerouting formed on the insulating member, where a portion of the rerouting is in contact with the exposed bonding pad; and
an external connecting terminal electrically connected to a portion of the rerouting,
wherein a portion of the insulating member overlapping the rerouting includes a plurality of spaces in which air is trapped.

2. The wafer level chip scale package of claim 1, wherein the insulating member comprises:
a passivation layer formed on a surface of the wafer;
a first interlayer insulating layer formed on the passivation layer, the first interlayer insulating layer including the plurality of spaces; and
a second interlayer insulating layer formed on the first interlayer insulating layer such that air is trapped in the plurality of spaces.

3. The wafer level chip scale package of claim 2, wherein the spaces of the first interlayer insulating layer form a mesh shape, the spaces of the mesh having a size of about 0.1 to about 100 microns.

4. The wafer level chip scale package of claim 2, wherein the first interlayer insulating layer is formed to include at least one selected from polyimide, polybenzoxazole (PBO), benzocyclobutene (BCB), and epoxy.

5. The wafer level chip scale package of claim 2, wherein the spaces are formed substantially throughout the first interlayer insulating layer.

6. The wafer level chip scale package of claim 1, wherein the insulating member comprises:
a passivation layer formed on a surface of the wafer;
a first interlayer insulating layer formed on the passivation layer, the first interlayer insulating layer including a first plurality of spaces;
a second interlayer insulating layer formed on the first interlayer insulating layer, the second interlayer insulating layer including a second plurality of spaces; and
a third interlayer insulating layer formed on the second interlayer insulating layer such that air is trapped in the first and second plurality of spaces.

7. The wafer level chip scale package of claim 6, wherein each space of the second plurality of spaces formed in the second interlayer insulating layer alternate with each space of the first plurality of spaces formed in the first interlayer insulating layer.

8. The wafer level chip scale package of claim 1, wherein the insulating member comprises:
a passivation layer formed on a surface of the wafer;
a first interlayer insulating layer formed on the passivation layer, the interlayer insulating layer including the plurality of spaces, where the plurality of spaces are interconnected to form a cave in which air can be trapped; and
at least one insulating post formed in the cave to support the interlayer insulating layer.

9. The wafer level chip scale package of claim 8, further comprising a second interlayer insulating layer formed on the wafer including the rerouting to expose a portion of the rerouting, wherein the second interlayer insulating layer includes substantially the same material as the insulating post.

10. The wafer level chip scale package of claim 1, wherein an interlayer insulating layer is formed on the wafer including the rerouting to expose a portion of the rerouting.

11. The wafer level chip scale package of claim 1, wherein the rerouting includes a seed metal layer and a main metal layer formed on the seed metal layer.

12. The wafer level chip scale package of claim 11, wherein the seed metal layer includes at least one selected from Ti/Cu, TiW/NiV, Ti/TiV, and Ti/Ni/Cu layers.

13. The wafer level chip scale package of claim 12, wherein the main metal layer includes a copper-containing layer.

14. A wafer level chip scale package comprising:
a wafer arranged with bonding pads;
a passivation layer formed on the wafer and exposing each of the bonding pads;
a first interlayer insulating layer formed on the passivation layer, the first interlayer insulating layer including holes exposing at least a portion of the passivation layer;
a second interlayer insulating layer formed on the first interlayer insulating layer such that air is trapped in the holes;
a plurality of reroutings formed on the second interlayer insulating layer, wherein a portion of each of the reroutings is respectively in contact with each of the bonding pads;
a third interlayer insulating layer formed on the wafer including the reroutings, the third interlayer insulating layer formed to expose a portion of each of the reroutings; and
a plurality of external connecting terminals respectively bonded to each of the exposed portions of the reroutings.

15. The wafer level chip scale package of claim 14, wherein the first interlayer insulating layer includes at least one selected from polyimide, polybenzoxazole (PBO), benzocyclobutene (BCB), and epoxy.

16. The wafer level chip scale package of claim 14, wherein the holes are formed substantially throughout the first interlayer insulating layer.

17. The wafer level chip scale package of claim 14, wherein a fourth interlayer insulating layer is interposed between the first interlayer insulating layer and the second interlayer insulating layer, the fourth interlayer insulating layer including a plurality of spaces to trap air.

18. The wafer level chip scale package of claim 17, wherein each space of the plurality of spaces in the fourth interlayer insulating layer interposed between the first and second interlayer insulating layers alternate with each hole of the plurality of holes in the first interlayer insulating layer.

19. A method for manufacturing a wafer level chip scale package, the method comprising:
forming a passivation layer on a wafer including a pad so that the pad is exposed;
forming an insulating member on the passivation layer, the insulating layer including a plurality of spaces to trap air;
forming a rerouting on the insulating member, where a portion of the rerouting is formed to be in contact with the pad;
forming an insulating layer on the wafer including the rerouting, the insulating layer exposing a portion of the rerouting; and
forming an external connecting terminal to be in contact with the exposed rerouting.

20. The method of claim 19, wherein the forming of the insulating member comprises:
forming the first interlayer insulating layer on the passivation layer;
performing an exposure and developing process on a portion of the first interlayer insulating layer to form a plurality of spaces in the first interlayer insulating layer; and
forming a second interlayer insulating layer on the first interlayer insulating layer so that air is trapped in the spaces.

21. The method of claim 20, wherein the second interlayer insulating layer is formed by laminating

22. The method of claim 20, wherein the spaces of the first interlayer insulating layer are formed on a portion overlapping the rerouting.

23. The method of claim 20, wherein the spaces of the first interlayer insulating layer are formed throughout the first interlayer insulating layer.

24. The method of claim 20, further comprising: forming an additional interlayer insulating layer on the first interlayer insulating layer before forming the second interlayer insulating layer; and
forming spaces on a predetermined portion of the additional interlayer insulating layer, where the second interlayer insulating layer is subsequently formed to trap air in the spaces formed on the additional interlayer insulating layer.

25. The method of claim 19, wherein the forming of the insulating member comprises:
forming a first interlayer insulating layer on the passivation layer;
forming a second interlayer insulating layer on the first interlayer insulating layer;
forming a plurality of holes in the second interlayer insulating layer to expose a portion of the first interlayer insulating layer; and
injecting a developing solution through the holes to form a cave by removing a portion of the first interlayer insulating layer.

26. The method of claim 25, wherein during the formation of the insulating layer on the rerouting, a portion of the material of the insulating layer is introduced through an interface between the rerouting and the second interlayer insulating layer and through the holes to form posts in the cave.

27. The method of claim 19, wherein forming the rerouting comprises:
forming a seed metal layer such that a portion of the seed layer is in contact with the pad; and
forming a main metal layer on the seed metal layer.

28. The method of claim 27, wherein the seed metal layer is formed by chemical vapor deposition or sputtering a material including at least one selected from Ti/Cu, TiW/NiV, Ti/TiV, and Ti/Ni/Cu.

29. The method of claim 27, wherein the main metal layer is formed by plating or sputtering a material including a copper-containing material.
